(19) United States
(12) Patent Application Publication
(10) Pub. No.: US 2025/0268009 A1
(43) Pub. Date: Aug. 21, 2025

(54) DISPLAY APPARATUS

(71) Applicant: LG Display Co., Ltd., Seoul (KR)

(72) Inventor: Jaeho KIM, Paju-si (KR)

(73) Assignee: LG Display Co., Ltd., Seoul (KR)

(21) Appl. No.: 19/042,726

(22) Filed: Jan. 31, 2025

(30) Foreign Application Priority Data
Feb. 20, 2024 (KR) 10-2024-0024354

(51) Int. Cl. H10H 29/85; H01L 23/13; H10H 29/852

(52) U.S. Cl. CPC H10H 29/8508; H01L 23/13; H10H 29/852

(57) ABSTRACT

A display apparatus can include a display panel on which a video is reproduced, a metal plate disposed behind the display panel, a first circuit board disposed behind the metal plate and electrically connected to the display panel, a chip on film, a driving element disposed on the chip on film and protruding from the chip on film, and a reinforcing plate disposed at a position at which at least a portion thereof overlaps the driving element behind the chip on film and adhered to the chip on film. The chip on film can have one side electrically connected to the display panel, another side electrically connected to the first circuit board, and a portion provided to be bent.

### CROSS REFERENCE TO RELATED APPLICATION

The present application claims priority to Korean Patent Application No. 10-2024-0024354, filed in the Republic of Korea on Feb. 20, 2024, the entire contents of which are hereby expressly incorporated by reference into the present application.

### BACKGROUND

### Field

The present disclosure relates to a display apparatus, and more specifically to, for example, without limitation, a display apparatus having a structure that protects a chip on film from an external impact.

### Discussion of the Related Art

Contents described in this section simply provide background information on the present application and do not constitute the related art.

In the full-fledged information age, the field of display apparatuses for visually displaying electrical information signals is developing rapidly. Research for developing enhanced performance, such as thinness, lightweight, and lower power consumption, for various display apparatuses is being continuously conducted.

Such display apparatuses include a liquid crystal display (LCD) apparatus, a quantum dot display panel apparatus (QD), a field emission display (FED) device, an electro-wetting display (EWD) apparatus, and an organic light emitting diode display (OLED) apparatus, etc.

The display apparatuses have been developed to be miniaturized so that users can carry the display apparatuses or so that they can be mounted on movable devices such as vehicles, etc., and are being improved so that the users can use the display apparatuses more conveniently.

The description provided in the discussion of the related art section should not be assumed to be prior art merely because it is mentioned in or associated with that section. The discussion of the related art section can include information that describes one or more aspects of the subject technology, and the description in this section does not limit the disclosure.

### SUMMARY OF THE DISCLOSURE

A display apparatus can be provided with a chip on film (COF). The chip on film can have a driving element for driving the display apparatus embedded therein. The chip on film can be made of a thin flexible material. Therefore, the chip on film is effective and efficient in increasing the convenience of assembly and reducing a space of components.

The chip on film can electrically connect a display panel to a printed circuit board. To this end, the chip on film can be disposed by being bent at a portion adjacent to an edge of the display panel. Therefore, the chip on film can protrude from a lower end of the display panel.

Meanwhile, the display apparatus can receive an external impact during use. For example, when the display apparatus is mounted on a movable device such as a vehicle, an external impact by the movement of the vehicle can be transmitted to the display apparatus.

Due to the external impact, the display apparatus can be deformed or in severe cases, damaged. In the case in which a damaged state is severe, fragments of the display apparatus can injure a user riding in a vehicle.

Even when the display apparatus is not damaged when receiving an external impact, some components of the display apparatus can be damaged by the external impact, which can cause a malfunction or failure of the display apparatus.

In particular, in the case of a display apparatus having a slim structure or a display apparatus provided with bendable flexible components, the influence of an external impact can be greater.

Since a chip on film is manufactured thinly, the chip on film can be vulnerable to an external impact. The chip on film can be damaged by such an external impact. Therefore, there is a need for the development for a technology of suppressing, minimizing or preventing damage to the chip on film which can be caused by an external impact.

In particular, since a driving element provided in the chip on film has a predetermined volume, the driving element can be provided to protrude from the chip on film. Therefore, when an external impact is applied to the chip on film, the flexible chip on film can easily move, and thus the driving element provided in the chip on film can also move.

In this case, the driving element can easily be damaged by moving and hitting other components of the display apparatus. Damage to the driving element can severely affect the entirety of the display apparatus. Therefore, there is a need for the development for a structure that protects the driving element from an external impact.

Therefore, the present disclosure is directed to providing a display apparatus having a structure that protects a chip on film and a driving element provided in the chip on film from an external impact.

In addition, the present disclosure is directed to providing a display apparatus having a reinforcing plate that protects a driving element of a chip on film from an external impact.

In addition, the present disclosure is directed to providing a display apparatus having a structure that has an avoidance part for protecting a driving element of a chip on film from an external impact.

In addition, the present disclosure is directed to providing a display apparatus having a pad that protects a driving element of a chip on film from an external impact.

Further, the present disclosure is directed to providing a display apparatus that addresses the limitations and disadvantages associated with the related art.

Objects of the present disclosure are not limited to the above-described objects, and other objects and advantages of the present disclosure which are not mentioned can be understood by the following description and more clearly understood by embodiments of the present disclosure. In addition, it will be able to be easily seen that the objects and advantages of the present disclosure can be achieved by devices and combinations thereof that are described in the claims.

A display apparatus according to one embodiment of the present disclosure can include a display panel on which a video is reproduced, a metal plate disposed behind the display panel, a first circuit board disposed behind the metal plate and electrically connected to the display panel, a chip on film (COF) having one side electrically connected to the display panel, another side electrically connected to the first circuit board, and a portion provided to be bent, a driving element disposed on the chip on film and protruding from the chip on film, and a reinforcing plate disposed at a position at which at least a portion thereof overlaps the driving element behind the chip on film and adhered to the chip on film.

According to aspects of the present disclosure, the driving element can protrude toward the first circuit board, and an avoidance part can be formed at a position corresponding to a position at which the driving element is disposed on the first circuit board.

According to aspects of the present disclosure, the avoidance part can be provided as a recessed groove formed by recessing an end portion of the first circuit board or a through hole formed by penetrating the first circuit board.

According to aspects of the present disclosure, the display apparatus can include a support pad disposed between the chip on film and the first circuit board to maintain a gap between the driving element and the first circuit board.

A display apparatus according to another embodiment of the present disclosure can include a display panel on which a video is reproduced, a metal plate disposed behind the display panel, a first circuit board disposed behind the metal plate and electrically connected to the display panel, a chip on film having one side electrically connected to the display panel, another side electrically connected to the first circuit board, and a portion provided to be bent, and a driving element disposed on the chip on film and protruding from the chip on film to the first circuit board, wherein an avoidance part can be formed at a position corresponding to a position at which the driving element is disposed on the first circuit board.

A display apparatus according to still another embodiment of the present disclosure can include a display panel on which a video is reproduced, a metal plate disposed behind the display panel, a first circuit board disposed behind the metal plate and electrically connected to the display panel, a chip on film having one side electrically connected to the display panel, another side electrically connected to the first circuit board, and a portion provided to be bent, a driving element disposed on the chip on film and protruding from the chip on film to the first circuit board, and a support pad disposed between the chip on film and the first circuit board to maintain a gap between the driving element and the first circuit board.

In the display apparatus according to aspects of the present disclosure, the reinforcing plate that reinforces the rigidity of the chip on film can be adhered to the chip on film.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure.

FIG. 1 is a front view showing the display apparatus according to one or more embodiments of the present disclosure.

FIG. 2 is a rear view showing an example of the display apparatus according to one embodiment of the present disclosure.

FIG. 3 is a side view showing a display apparatus according to one embodiment of the present disclosure.

FIG. 4 is an exploded view showing the display apparatus according to one embodiment of the present disclosure.

FIG. 5 is an enlarged view showing a portion of a side surface the display apparatus according to one embodiment of the present disclosure.

FIG. 6 is a view for describing an object that the present disclosure aims to achieve.

FIG. 7 is a view showing a display apparatus having a structure according to one or more embodiments of the present disclosure.

FIG. 8 is a cross-sectional view along line 8-8′ in FIG. 7.

FIG. 9 is a view showing a display apparatus having a structure according to another embodiment of the present disclosure.

FIG. 10 is a view showing a display apparatus having a structure according to still another embodiment of the present disclosure.

FIG. 11 is a cross-sectional view along line 11-11′ in FIG. 10.

FIG. 12 is a view showing a display apparatus having a structure according to yet another embodiment of the present disclosure.

FIG. 13 is a cross-sectional view along line 13-13′ in FIG. 12.

FIG. 14 is a view showing a display apparatus having a structure according to yet another embodiment of the present disclosure.

FIG. 15 is a cross-sectional view along line 15-15′ in FIG. 14.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

The above-described objects, features, and advantages will be described below in detail with reference to the accompanying drawings, and thus those skilled in the art to which the present disclosure pertains will be able to easily carry out the technical idea of the present disclosure. In describing the present disclosure, when it is determined that a detailed description of the known technology related to the present disclosure can unnecessarily obscure the gist of the present disclosure, a detailed description thereof will be omitted or can be briefly provided. Hereinafter, example embodiments according to the present disclosure will be described in detail with reference to the accompanying drawings. In the drawings, the same reference numerals are used to denote the same or similar components.

Although the terms “first,” “second,” etc. are used to describe various components, it goes without saying that these components are not limited by these terms. These terms are used only to distinguish one component from another component and may not define order or sequence. Unless otherwise stated, it goes without saying that a first component can be a second component.

Throughout the specification, unless otherwise stated, each component can be singular or plural. Throughout the drawings and the detailed description, unless otherwise described, the same drawing reference numerals should be understood to refer to the same elements, features, and structures. The relative size and depiction of these elements can be exaggerated for clarity, illustration, and convenience.

The singular expression used herein includes the plural expression unless the context clearly dictates otherwise. In the application, terms such as “composed of” or “comprising” should not be construed as necessarily including all of the various components or operations described in the specification and should be construed that some of the components or some of the operations may not be included or additional components or operations can be further included.

Throughout the specification, when “A and/or B” is described, this means A, B, or A and B unless otherwise specified, and when “C to D” is described, this means C or more and D or less unless otherwise specified.

Reference will now be made in detail to embodiments of the present disclosure, examples of which can be illustrated in the accompanying drawings. In the following description, when a detailed description of well-known functions or configurations related to this document is determined to unnecessarily obscure a gist of the inventive concept, the detailed description thereof will be omitted or can be briefly provided. The progression of processing steps and/or operations described is an example; however, the sequence of steps and/or operations is not limited to that set forth herein and can be changed as is known in the art, with the exception of steps and/or operations necessarily occurring in a particular order. Like reference numerals designate like elements throughout. Names of the respective elements used in the following explanations can be selected only for convenience of writing the specification and can be thus different from those used in actual products.

Any implementation described herein as an “example” is not necessarily to be construed as preferred or advantageous over other implementations.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may.”

In the description of the various embodiments of the present disclosure, where positional relationships are described, for example, when a position relation between two parts is described as, for example, “on,” “over,” “under,” and “next,” or the like, one or more other parts can be located between the two parts unless a more limiting term, such as “just” or “direct(ly)” is used. For example, where an element or layer is disposed “on” another element or layer, a third element or layer can be interposed therebetween.

In describing a temporal relationship, when the temporal order is described as, for example, “after,” “subsequent,” “next,” and “before,” a case that is not continuous can be included unless a more limiting term, such as “just,” “immediate(ly),” or “direct(ly)” is used.

Also, when an element or layer is “connected,” “coupled,” or “adhered” to another element or layer denotes that the element or layer may not only be directly connected or adhered to the other element or layer, but also be indirectly connected or adhered to the other element or layer with one or more intervening elements or layers “disposed,” or “interposed” between the elements or layers, unless otherwise specified. It should be understood to mean that elements can be so disposed to directly contact each other, or can be so disposed without directly contacting each other.

It will be apparent to those skilled in the art that various modifications and variations can be made to the embodiments of the present disclosure without departing from the technical idea or scope of the present disclosure. Thus, it is intended that the present disclosure covers the modifications and variations of this disclosure provided they come within the scope of the appended claims and their equivalents.

A display apparatus according to an embodiment of the present disclosure can be, for example, mounted in front of a front seat inside a vehicle to provide a driver and passengers of the vehicle with a video or image necessary for driving. However, the present disclosure is not limited thereto, and the display apparatus can be used while carried by the user rather than mounted on the vehicle. Hereinafter, for example, a display apparatus mounted on a vehicle will be described.

All the components of each display apparatus according to all embodiments of the present disclosure are operatively coupled and configured.

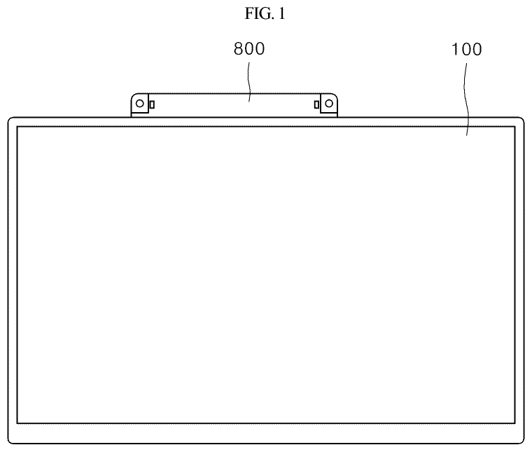

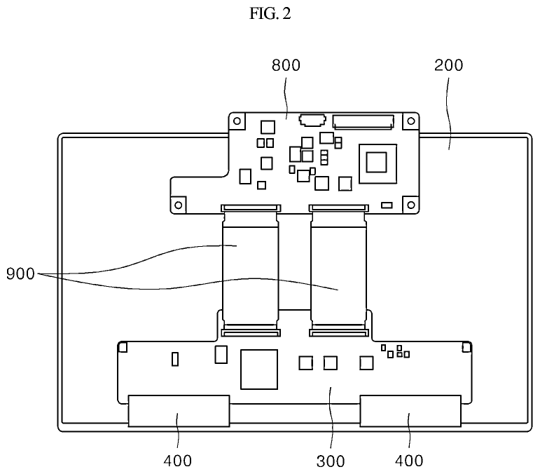

FIG. 1 is a front view showing the display apparatus according to one or more embodiments of the present disclosure. FIG. 2 is a rear view showing the display apparatus according to one embodiment of the present disclosure.

Referring to FIGS. 1 and 2, the display apparatus according to the embodiment can include a display panel 100, a metal plate 200, and a first circuit board 300.

A video or image can be reproduced on the display panel 100. The video or image to be displayed can be navigation information necessary for traveling, video captured by a camera mounted on the vehicle, or various other contents needed by a driver or passengers.

The metal plate 200 can be disposed behind the display panel 100. The metal plate 200 can be formed thinly to manufacture a slim display panel 100. The metal plate 200 can serve as a heat sink for protecting the display panel 100 and dissipating heat generated from the display panel 100 to the outside to cool the display panel 100.

The metal plate 200 can be made of, for example, aluminum or an alloy material including aluminum.

The first circuit board 300 can be disposed behind the metal plate 200 and electrically connected to the display panel 100. The first circuit board 300 can include a camera, a device for communicating with external devices such as a main control module of a vehicle, a device for driving the display panel 100 so that the display panel 100 reproduces a video or image, etc., and can be provided with a circuit and various other active and passive elements.

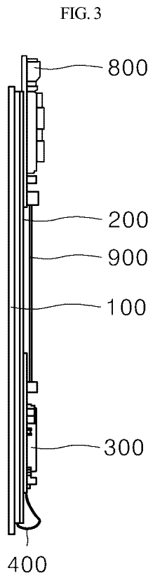

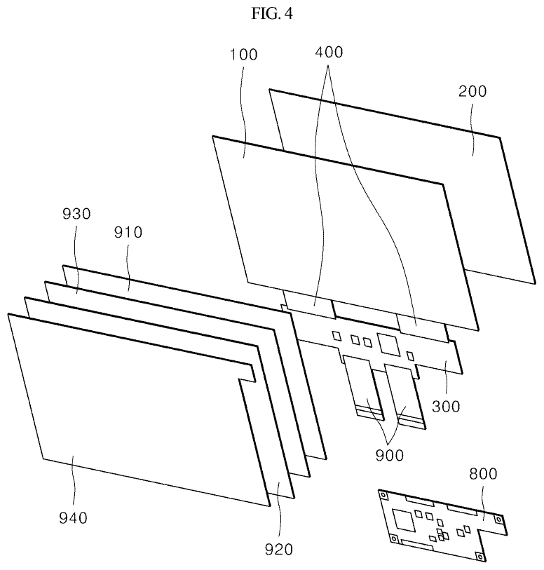

FIG. 3 is a side view showing a display apparatus according to one embodiment of the present disclosure. FIG. 4 is an exploded view showing the display apparatus according to one embodiment of the present disclosure.

Referring to FIGS. 3 and 4, the display apparatus according to one embodiment of the present disclosure can include a chip on film (COF) 400.

The chip on film 400 can have one side electrically connected to the display panel 100, the other side electrically connected to the first circuit board 300, and a portion provided to be bent.

The chip on film 400 can be formed thinly and made of a bendable flexible material. The chip on film 400 can electrically connect the display panel 100 with the first circuit board 300. The chip on film 400 can be provided with various active and passive elements and provided with a driving circuit for driving the display panel 100.

The driving circuit for driving the display panel 100 can be provided to be dispersed to each of the first circuit board 300 and the chip on film 400. The chip on film 400 can include a driving element 500 for driving the display panel 100. For example, the chip on film 400 can be provided with the driving element 500 that forms at least a portion of the driving circuit of the display panel 100.

FIG. 5 is an enlarged view showing a portion of a side surface the display apparatus according to one embodiment of the present disclosure.

Referring to FIG. 5, the driving element 500 can be disposed on the chip on film 400 and can protrude from the chip on film 400.

The driving element 500 can be provided as an integrated circuit (IC) for controlling an operation of the display apparatus. Since the driving element 500 is provided with various circuit structures for implementing control logic, the driving element 500 can have a certain volume. Therefore, the driving element 500 can be coupled to the chip on film 400 and can protrude from the chip on film 400.

The display apparatus can include a second circuit board 800 and a flexible circuit board 900. The second circuit board 800 can be disposed behind the display panel 100 to be spaced apart from the first circuit board 300.

The second circuit board 800 can connect a control unit provided in the vehicle to the first circuit board 300 to supply electricity to the first circuit board 300. The second circuit board 800 can be provided with various active elements, passive elements, and electric circuits to play their roles.

The flexible circuit board 900 can electrically connect the first circuit board 300 to the second circuit board 800. The flexible circuit board 900 can be made of a flexible material and can serve as a cable.

The flexible circuit board 900 can be made of a flexible material so that arrangement positions and arrangement shapes of the first circuit board 300 and the second circuit board 800 can be freely adjusted. The flexible circuit board 900 can be provided with various active elements, passive elements, and electric circuits to play their roles.

Since the chip on film 400 and the flexible circuit board 900 are made of a flexible material, when the display apparatus is assembled, the chip on film 400 and the flexible circuit board 900 can move flexibly, thereby improving the convenience of assembly and manufacturing a slim display apparatus.

Meanwhile, a plurality of light sources can be disposed on the display panel 100 to be spaced apart from each other to radiate light to reproduce a video. Such a light source can be provided, for example, as a light emitting diode (LED) 110.

The display apparatus can include a polarizer 910, a front cover 920, a first adhesive layer 930, and a protective film 940.

The polarizer 910 can be disposed in front of the display panel 100. The polarizer 910 can convert the light radiated from the display panel 100 into circularly polarized light. The polarizer 910 can increase outdoor visibility and contrast ratio for the video displayed on the display panel 100 by alleviating or preventing reflection of external light.

The front cover 920 can be disposed in front of the polarizer 910. The front cover 920 can be disposed in front of the display panel 100 to protect the display panel 100. The front cover 920 can be made of a transparent material so that light radiated from the front cover 920 can pass through the front cover 920.

The front cover 920 can be made of, for example, transparent glass or transparent plastic, but is not limited thereto.

The front cover 920 can be formed relatively thick to protect other components positioned therebehind and maintain the rigidity of the entirety of the display apparatus, thereby alleviating or preventing the display apparatus from being easily deformed by an external impact.

The first adhesive layer 930 can be disposed between the front cover 920 and the polarizer 910 and can adhere the front cover 920 and the polarizer 910.

The first adhesive layer 930 can be provided in the form of a film or plate and made of an adhesive material. The first adhesive layer 930 can be made of a transparent material with high light transmittance.

The first adhesive layer 930 can be made of or can include a material that has good adhesion, such as an optical clear adhesive (OCA), an optical clear resin (OCR), or a pressure sensitive adhesive (PSA).

The protective film 940 can be disposed in front of the front cover 920. The protective film 940 can be formed of a thin film to protect a surface of the front cover 920. However, the protective film 940 is not an essential component of the display apparatus.

The display apparatus can include a touch input part 911, a second adhesive layer 950, and a protective layer 960. The touch input part 911 can be disposed between the display panel 100 and the polarizer 910. The touch input part 911 can receive and transmit a user's command to a control unit. Of course, the touch input part 911 can operate in an electrostatic manner.

The protective layer 960 can be disposed behind the display panel 100 and can protect the display panel 100. The protective layer 960 can be made of, for example, glass or a plastic material, but is not limited thereto.

The second adhesive layer 950 can be disposed between the metal plate 200 and the protective layer 960 and can adhere the metal plate 200 and the protective layer 960. The second adhesive layer 950 can be made of a material that is the same as or similar to that of the first adhesive layer 930.

For example, the second adhesive layer 950 can be provided in the form of a film or plate and made of an adhesive material. The first adhesive layer 930 can be made of or can include a material having good adhesive strength, for example, OCA, OCR, or PSA. The second adhesive layer 950 can be made of a transparent or opaque material.

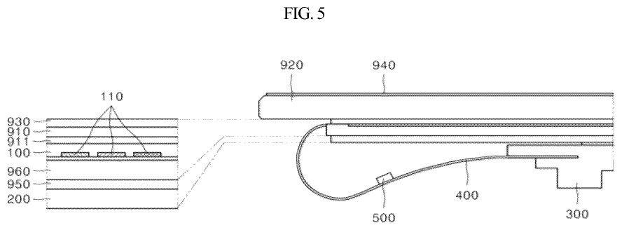

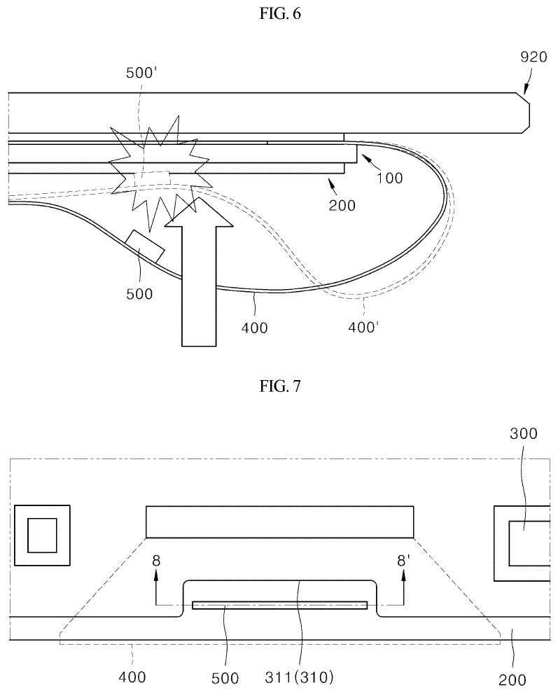

FIG. 6 is a view for describing an object which the present disclosure aims to achieve. Arrows shown in FIG. 6 indicate an external impact applied to the chip on film 400 having the driving element 500 and its direction.

As shown in FIG. 6, to protect the driving element 500, the chip on film 400 can be bent so that a protruding surface on which the driving element 500 is mounted is disposed therein, thereby alleviating or preventing the chip on film 400 from being exposed to the outside.

The display apparatus can receive an external impact when a vehicle provided with the display apparatus suddenly accelerates or stops, when a user drops a portable display apparatus, or due to various other reasons.

When an external impact is applied to the chip on film 400, the chip on film 400 can be deformed, and thus the driving element 500 can move and collide with other components of the display apparatus. The driving element 500 has a certain volume and thus protrudes from the surface of the chip on film 400. For example, the driving element 500 can collide with a back surface of the first circuit board 300 or the metal plate 200 that the chip on film 400 faces.

Due to such collision, the driving element 500 can be damaged, and the damage to the driving clement 500 can adversely affect the display operation. Therefore, there is a need for a structure capable of suppressing the damage to the driving element 500 due to an external impact. This will be described in detail below.

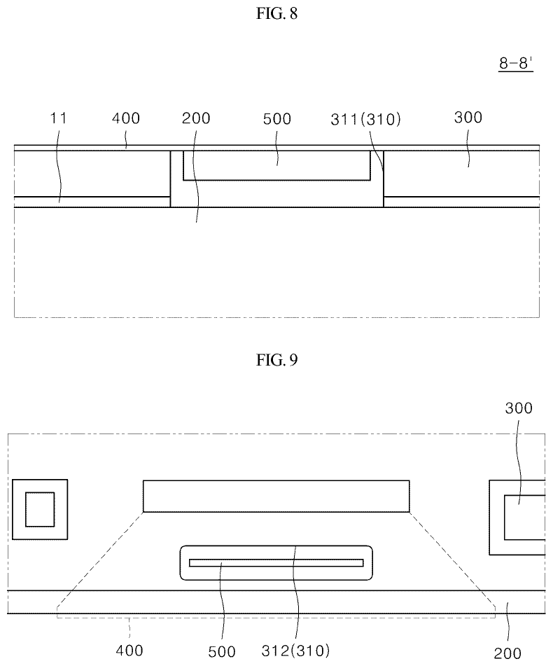

FIG. 7 is a view showing a display apparatus having a structure according to one or more embodiments of the present disclosure. FIG. 8 is a cross-sectional view along line 8-8′ in FIG. 7.

Referring to FIGS. 7 and 8, as described above, the driving element 500 can protrude toward the first circuit board 300. Therefore, when an external impact is applied to the chip on film 400 and the driving element 500, the driving element 500 can collide with the first circuit board 300.

To alleviate or prevent such collision, an avoidance part 310 can be formed at a position corresponding to a position at which the driving element 500 is disposed on the first circuit board 300. The avoidance part 310 can alleviate or prevent the driving element 500 from colliding with the first circuit board 300 even when the driving element 500 moves.

The avoidance part 310 can be provided as a recessed groove 311 or a through hole 312 (or a combination thereof). When the avoidance part 310 is formed on the first circuit board 300, the driving element 500 can face the metal plate 200 in the front-rear direction of the display apparatus when the driving element 500 is positioned on the avoidance part 310.

In an embodiment of the present disclosure, a thickness of the first circuit board 300 can be provided to be larger than a protruding height of the driving element 500. Therefore, since there is a free space between an end of the driving element 500 and the metal plate 200, the driving element 500 and the metal plate 200 may not collide.

With this structure, the avoidance part 310 formed on the first circuit board 300 can suppress the driving element 500 from colliding with the first circuit board 300 and the metal plate 200. Therefore, it is possible to alleviate or prevent the driving element 500 of the chip on film 400 from being damaged by colliding with other components due to an external impact, thereby effectively increasing the durability of the display apparatus.

First, the avoidance part 310 provided as the recessed groove 311 will be described. As shown in FIG. 7, the avoidance part 310 can be provided as the recessed groove 311 formed by recessing an end portion of the first circuit board 300.

Depending on the position at which the driving element 500 is disposed on the chip on film 400, a component that the driving element 500 faces can vary. When viewed in the front-rear direction of the display apparatus, the first circuit board 300 can have a smaller area than the metal plate 200.

Therefore, the driving element 500 can be disposed at a position adjacent to a boundary point between the first circuit board 300 and the metal plate 200. In this case, the driving element 500 on the chip on film 400 deformed by an external impact can collide with the boundary point between the first circuit board 300 and the metal plate 200.

Correspondingly, the recessed groove 311 can be formed in the end portion of the first circuit board 300. Referring to FIG. 8, the recessed groove 311 can form a space that protects the driving element 500, thereby alleviating or preventing the driving element 500 from colliding with the first circuit board 300 or the metal plate 200.

Meanwhile, a plate-shaped adhesive part 11 can be provided between the metal plate 200 and the first circuit board 300. The adhesive part 11 can adhere the metal plate 200 and the first circuit board 300 and can be formed of an adhesive having a predetermined thickness.

An avoidance structure corresponding to the avoidance part 310 of the first circuit board 300 can also be formed on the adhesive part 11. Since the adhesive part 11 has a thickness, the driving element 500 and the metal plate 200 can be spaced apart from each other at the avoidance part 310, thereby alleviate or preventing collision therebetween.

Therefore, when the height of the driving element 500 is somewhat large, the adhesive part 11 can be formed to be somewhat thick to form a sufficient separation distance between the driving element 500 and the metal plate 200.

Meanwhile, when no external impact is applied to the chip on film 400, the chip on film 400 is not deformed to maintain its original shape, and in this case, the driving element 500 can be sufficiently spaced apart from the first circuit board 300, and thus the driving element 500 may not be disposed in the recessed groove 311 but can be disposed at a position spaced apart from the recessed groove 311.

When an external impact is applied to the chip on film 400, the driving element 500 can move to be disposed in the recessed groove 311. This structure is also the same when the avoidance part 310 to be described below is provided as the through hole 312.

However, in another embodiment of the present disclosure, a case in which the chip on film 400 is adhered to the first circuit board 300 can be an exception. This will be described in detail below.

FIG. 9 is a view showing a display apparatus having a structure according to another embodiment of the present disclosure. A cross-sectional structure of FIG. 9 can be similar to the structure shown in FIG. 8. As shown in FIG. 9, the avoidance part 310 can be provided as the through hole 312 formed by penetrating the first circuit board 300.

Depending on the position at which the driving element 500 is disposed on the chip on film 400, the driving element 500 can be positioned at a position facing the first circuit board 300. Therefore, when an external impact is applied to the chip on film 400, the driving element 500 can collide with the first circuit board 300.

Correspondingly, the through hole 312 can be formed in the first circuit board 300. Referring to FIG. 9, the through hole 312 can form a space that protects the driving element 500, thereby alleviating or preventing the driving element 500 from colliding with the first circuit board 300 or the metal plate 200.

Since the through hole 312 is formed at the position facing the driving element 500 and passes through the first circuit board 300 so that the metal plate 200 is visible, when an external impact is applied to the chip on film 400, the driving element 500 can be disposed in the through hole 312 formed in the first circuit board 300, and the driving element 500 and the metal plate 200 can maintain a state of being spaced apart from each other, and thus the driving element 500 can avoid colliding with the first circuit board 300 and the metal plate 200.

According to another embodiment of the present disclosure, the chip on film 400 can be provided to have at least a portion adhered to the first circuit board 300 in a state in which the driving element 500 is accommodated in the avoidance part 310.

When the chip on film 400 is electrically connected to the first circuit board 300 but is not adhered thereto, when the chip on film 400 is deformed by an external impact, the driving element 500 may not be accommodated in the avoidance part 310 formed on the first circuit board 300.

For example, when the degree of deformation of the chip on film 400 by an external impact is great, the driving element 500 can greatly deviate from its original position and can be damaged by colliding with another portion of the first circuit board 300 or the metal plate 200 other than the avoidance part 310.

Therefore, when the chip on film 400 is bonded to the first circuit board 300 with an adhesive to maintain a state in which the driving element 500 is accommodated in the space of the avoidance part 310, even when the chip on film 400 is greatly deformed, the driving element 500 can always be disposed on the avoidance part 310, thereby effectively alleviating or preventing the driving element 500 from colliding with the first circuit board 300 or the metal plate 200.

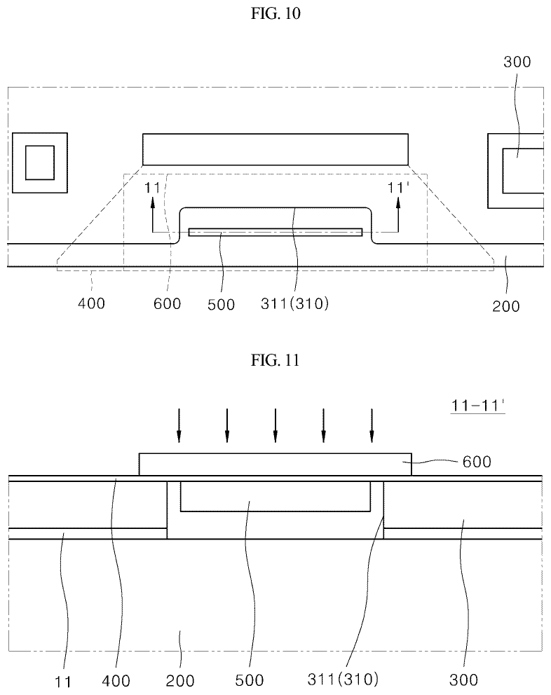

FIG. 10 is a view showing a display apparatus having a structure according to still another embodiment of the present disclosure. FIG. 11 is a cross-sectional view along line 11-11′ in FIG. 10. Arrows shown in FIG. 11 indicate an external impact applied to the chip on film 400 and its direction.

Referring to FIGS. 10 and 11, the display apparatus can include a reinforcing plate 600 that is disposed at a position at which at least a portion thereof overlaps the driving element 500 behind the chip on film 400 and is adhered to the chip on film 400. The reinforcing plate 600 can be adhered to an outer surface of the chip on film 400, that is, a surface opposite to a surface from which the driving element 500 protrudes, using an adhesive.

The reinforcing plate 600 is provided in the form of a thin film, but can be provided to have an appropriate thickness so as not to be deformed by an external impact. The reinforcing plate 600 can be made of, for example, copper, aluminum, an alloy including the same, or stainless steel.

Although the quadrangular reinforcing plate 600 is shown in the drawing, the reinforcing plate 600 is not limited thereto and can be manufactured in any shape such as a circle, oval, or polygon.

Since the reinforcing plate 600 is not deformed by an external impact, the reinforcing plate 600 can protect the chip on film 400 that is easily deformed by an external impact. Therefore, it is possible to alleviate or prevent the chip on film 400 from being deformed by an external impact to suppress the movement of the driving element 500, thereby alleviating or preventing the driving clement 500 from colliding with other components.

In particular, when an external impact is applied to a portion of the chip on film 400 adjacent to the driving clement 500, the portion of the chip on film 400 adjacent to the driving element 500 can be deformed. With this deformation, even when the driving element 500 is disposed on the avoidance part 310, the chip on film 400 is continuously deformed, and the driving element 500 can continuously move in a state of being disposed on the avoidance part 310 and collide with the first circuit board 300 or the metal plate 200.

In this case, when the reinforcing plate 600 is provided, the chip on film 400 is not deformed at the portion where the driving element 500 is disposed by the reinforcing plate 600, and thus it is possible to suppress the movement of the driving element 500, thereby effectively alleviating or preventing damage due to collision.

Although FIG. 11 shows the case in which the avoidance part 310 is provided as the recessed groove 311, the case in which the avoidance part 310 is provided as the through hole 312 can also be described similar to the above-described contents.

The avoidance part 310 can be disposed at a position at which at least a portion thereof overlaps the reinforcing plate 600. The avoidance part 310 and the reinforcing plate 600 can be disposed so that at least portions thereof overlap each other in the front-rear direction, thereby very effectively alleviating or preventing the deformation of a portion adjacent to the driving element 500 disposed in the avoidance part 310 on the chip on film 400.

In addition, the reinforcing plate 600 can be attached to the chip on film 400 at a portion overlapping the avoidance part 310 of the entire chip on film 400, thereby effectively reducing an area of the reinforcing plate 600 and at the same time, effectively alleviating or preventing damage to the driving element 500 due to collision.

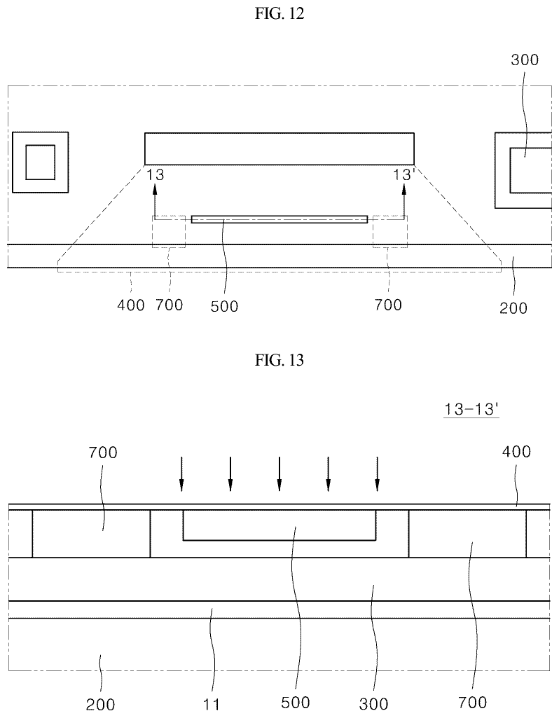

FIG. 12 is a view showing a display apparatus having a structure according to yet another embodiment of the present disclosure. FIG. 13 is a cross-sectional view along line 13-13′ in FIG. 12.

Referring to FIGS. 12 and 13, the driving element 500 can protrude toward the first circuit board 300. In this case, the display apparatus can include a support pad 700 that is disposed between the chip on film 400 and the first circuit board 300 to maintain a gap between the driving element 500 and the first circuit board 300.

The support pad 700 can be provided in any form when separating the driving element 500 and the first circuit board 300. FIG. 12 shows a pair of support pads 700 disposed at both sides of the driving element 500 with the driving element 500 interposed therebetween.

However, as another embodiment of the present disclosure, four support pads 700 disposed at the top, bottom, left, and right of the driving element 500 can be provided, or the support pad 700 can be provided in the form of a closed curve surrounding the driving element 500.

The support pad 700 can separate the first circuit board 300 from the driving element 500 in the front-rear direction to suppress the driving element 500 from colliding with the first circuit board 300 or the metal plate 200 even when an external impact is applied, thereby effectively alleviating or preventing damage to the driving element 500 due to collision.

Depending on the position at which the driving element 500 is disposed on the chip on film 400, the driving element 500 can collide with the first circuit board 300 or the metal plate 200 or collide with the boundary between the first circuit board 300 and the metal plate 200.

Since the support pad 700 separates the first circuit board 300 and the metal plate 200 from the driving element 500, when the support pad 700 is disposed according to the embodiment of the present disclosure shown in FIG. 12, unlike the above-described embodiment of the present disclosure, the chip on film 400 can be disposed at a position directly facing the metal plate 200.

Therefore, in the case of the embodiment using the support pad 700, there is no need to arrange the driving element 500 at the position facing the first circuit board 300, and thus the chip on film 400 and the driving clement 500 can be designed more freely.

The support pad 700 can be provided to be adhered to at least one of the metal plate 200 or the first circuit board 300.

As described above, depending on the design, the driving element 500 can be disposed on the metal plate 200 or the first circuit board 300, or on the boundary between the metal plate 200 and the first circuit board 300. Therefore, correspondingly, the support pad 700 can be adhered to an appropriate position of the metal plate 200 or the first circuit board 300 using an adhesive so that the driving element 500 is spaced apart from the metal plate 200 and the first circuit board 300.

In another embodiment of the present disclosure, the support pad 700 can be adhered to the chip on film 400 and disposed to surround the driving element 500 to separate the driving element 500 from the metal plate 200 or the first circuit board 300.

When the degree of deformation of the chip on film 400 is large due to a great external impact, the driving element 500 can deviate from its original position and may not be protected by the support pad 700 and can be damaged by colliding with another portion of the first circuit board 300 or the metal plate 200.

To solve this issue, as still another embodiment of the present disclosure, the support pad 700 can be adhered to both the chip on film 400 and the metal plate 200 and/or the first circuit board 300.

For example, the support pad 700 can be provided to have one surface adhered to at least one of the metal plate 200 or the first circuit board 300 and the other surface adhered to the chip on film 400.

With this structure, the driving element 500 can always maintain a state of being spaced apart from the metal plate or the first circuit board 300 in the front-rear direction at a position protected by the support pad 700.

Therefore, even when the chip on film 400 is greatly deformed, the driving element 500 is fixed in position by the support pad 700 and does not move, and the driving element 500 can be effectively alleviated or prevented from colliding with the first circuit board 300 or the metal plate 200.

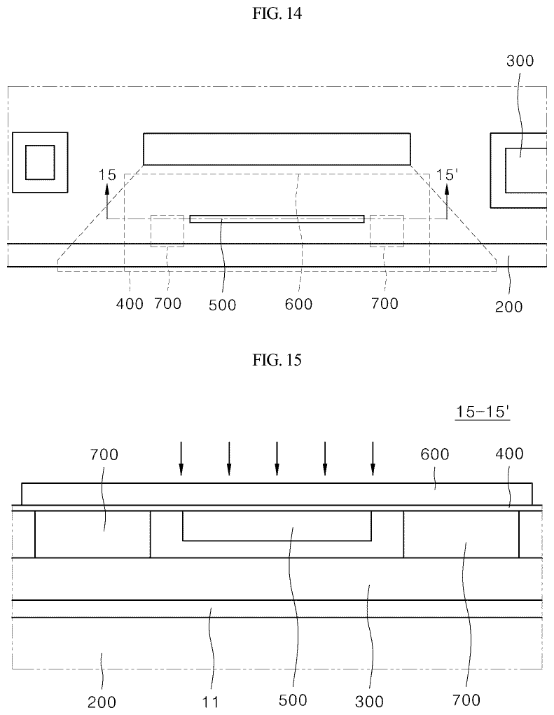

FIG. 14 is a view showing a display apparatus having a structure according to yet another embodiment of the present disclosure. FIG. 15 is a cross-sectional view along line 15-15′ in FIG. 14.

Referring to FIGS. 14 and 15, the display apparatus can further include the reinforcing plate 600 in a structure provided with the support pad 700.

The display apparatus can include the reinforcing plate 600 that is disposed at a position at which at least a portion thereof overlaps the driving element 500 behind the chip on film 400 and is adhered to the chip on film 400. The reinforcing plate 600 can be adhered to the outer surface of the chip on film 400, that is, the surface opposite to the surface from which the driving element 500 protrudes, using an adhesive.

The structure and effect of the reinforcing plate 600 are the same as or similar to those described above with reference to FIGS. 10 and 11.

Display apparatuses according to aspects of the present disclosure can be described as follows.

A display apparatus according to one embodiment of the present disclosure can include a display panel on which a video is reproduced, a metal plate disposed behind the display panel, a first circuit board disposed behind the metal plate and electrically connected to the display panel, a chip on film (COF) having one side electrically connected to the display panel, another side electrically connected to the first circuit board, and a portion provided to be bent, a driving element disposed on the chip on film and protruding from the chip on film, and a reinforcing plate disposed at a position at which at least a portion thereof overlaps the driving element behind the chip on film and adhered to the chip on film.

The driving element can protrude toward the first circuit board, and an avoidance part can be formed at a position corresponding to a position at which the driving element is disposed on the first circuit board.

The avoidance part can be provided as a recessed groove formed by recessing an end portion of the first circuit board.

The avoidance part can be provided as a through hole formed by penetrating the first circuit board.

The chip on film can be provided to have at least a portion adhered to the first circuit board in a state in which the driving element is accommodated in the avoidance part.

The driving element can protrude toward the first circuit board, and the display apparatus can include a support pad that is disposed between the chip on film and the first circuit board to maintain a gap between the driving element and the first circuit board.

The support pad can be provided to have one surface adhered to at least one of the metal plate or the first circuit board.

The support pad can be provided to have the other surface adhered to the chip on film.

The avoidance part can be disposed at a position at which at least a portion thereof overlaps the reinforcing plate.

The display apparatus can include a second circuit board disposed behind the display panel to be spaced apart from the first circuit board, and a flexible circuit board electrically connecting the first circuit board to the second circuit board.

The display apparatus can include a polarizer disposed in front of the display panel, a front cover disposed in front of the polarizer, a first adhesive layer disposed between the front cover and the polarizer, and a protective film disposed in front of the front cover.

A display apparatus according to another embodiment of the present disclosure can include a display panel on which a video is reproduced, a metal plate disposed behind the display panel, a first circuit board disposed behind the metal plate and electrically connected to the display panel, a chip on film having one side electrically connected to the display panel, another side electrically connected to the first circuit board, and a portion provided to be bent, and a driving element disposed on the chip on film and protruding from the chip on film to the first circuit board, wherein an avoidance part can be formed at a position corresponding to a position at which the driving element is disposed on the first circuit board.

The avoidance part can be provided as a recessed groove formed by recessing an end portion of the first circuit board.

The avoidance part can be provided as a through hole formed by penetrating the first circuit board.

The display apparatus can include a reinforcing plate that is disposed at a position at which at least a portion thereof overlaps the driving element behind the chip on film and adhered to the chip on film.

The chip on film can be provided to have at least a portion adhered to the first circuit board in a state in which the driving element is accommodated in the avoidance part.

A display apparatus according to still another embodiment of the present disclosure can include a display panel on which a video is reproduced, a metal plate disposed behind the display panel, a first circuit board disposed behind the metal plate and electrically connected to the display panel, a chip on film having one side electrically connected to the display panel, another side electrically connected to the first circuit board, and a portion provided to be bent, a driving element disposed on the chip on film and protruding from the chip on film to the first circuit board, and a support pad disposed between the chip on film and the first circuit board to maintain a gap between the driving element and the first circuit board.

The support pad can be provided to have one surface adhered to at least one of the metal plate or the first circuit board.

The support pad can be provided to have the other surface adhered to the chip on film.

The display apparatus can include a reinforcing plate that is disposed at a position at which at least a portion thereof overlaps the driving element behind the chip on film and adhered to the chip on film.

Since the reinforcing plate is not deformed by an external impact, it is possible to protect the chip on film that is easily deformed by the external impact. Therefore, by alleviating or preventing the chip on film from being deformed by an external impact to suppress the movement of the driving element, it is possible to alleviate or prevent the driving element from colliding with other components.

In addition, in the display apparatus according to the present disclosure, an avoidance part can be formed at a position corresponding to a position at which the driving element is disposed on the first circuit board. The avoidance part can alleviate or prevent the driving element from colliding with the first circuit board even when the driving element moves.

Therefore, it is possible to alleviate or prevent the driving element of the chip on film from being damaged by colliding with other components due to an external impact, thereby effectively increasing the durability of the display apparatus.

In addition, the display apparatus according to the present disclosure can include a support pad that is disposed between the chip on film and the first circuit board to maintain a gap between the driving element and the first circuit board.

According to aspects of the present disclosure, the support pad can separate the first circuit board from the driving element in the front-rear direction to suppress the driving element from colliding with the first circuit board or the metal plate even when an external impact is applied, thereby effectively alleviating or preventing the driving element from being damaged due to collision.

Specific effects together with the above-described effects of the present disclosure are described together with a description of the above-described detailed matters for carrying out the disclosure.

Although the present disclosure has been described above with reference to exemplary drawings, the present disclosure is not limited by the embodiments and drawings disclosed in the specification, and it is apparent that various modifications can be made by those skilled in the art within the scope of the technical idea of the present disclosure. In addition, even when the operational effects according to the configuration of the present disclosure have not been explicitly described in the description of the embodiments of the present disclosure, it goes without saying that the effects predictable by the corresponding configuration should be recognized.

What is claimed is:

1. A display apparatus comprising:
a display panel configured to reproduce a video;
a metal plate disposed behind the display panel;
a first circuit board disposed behind the metal plate and electrically connected to the display panel;
a chip on film having one side electrically connected to the display panel, another side electrically connected to the first circuit board, and a portion provided to be bent;
a driving element disposed on the chip on film and protruding from the chip on film; and
a reinforcing plate disposed at a position at which at least a portion thereof overlaps the driving element behind the chip on film and adhered to the chip on film.

2. The display apparatus of claim 1, wherein the driving element protrudes toward the first circuit board, and
an avoidance part is formed at a position corresponding to a position at which the driving element is disposed on the first circuit board.

3. The display apparatus of claim 2, wherein the avoidance part is provided as a recessed groove formed by recessing an end portion of the first circuit board.

4. The display apparatus of claim 2, wherein the avoidance part is provided as a through hole formed by penetrating the first circuit board.

5. The display apparatus of claim 2, wherein the chip on film is provided to have at least a portion adhered to the first circuit board in a state in which the driving element is accommodated in the avoidance part.

6. The display apparatus of claim 1, wherein the driving element protrudes toward the first circuit board, and
the display apparatus further comprises a support pad disposed between the chip on film and the first circuit board to maintain a gap between the driving element and the first circuit board.

7. The display apparatus of claim 6, wherein the support pad is provided to have a first surface adhered to at least one of the metal plate or the first circuit board.

8. The display apparatus of claim 7, wherein the support pad is provided to have a second surface adhered to the chip on film.

9. The display apparatus of claim 3, wherein the avoidance part is disposed at a position at which at least a portion thereof overlaps the reinforcing plate.

10. The display apparatus of claim 1, comprising:
a second circuit board disposed to be spaced apart from the first circuit board behind the display panel; and
a flexible circuit board electrically connecting the first circuit board to the second circuit board.

11. The display apparatus of claim 1, comprising:
a polarizer disposed in front of the display panel;
a front cover disposed in front of the polarizer;
a first adhesive layer disposed between the front cover and the polarizer; and
a protective film disposed in front of the front cover.

12. A display apparatus comprising:
a display panel configured to reproduce a video;
a metal plate disposed behind the display panel;
a first circuit board disposed behind the metal plate and electrically connected to the display panel;
a chip on film having one side electrically connected to the display panel, another side electrically connected to the first circuit board, and a portion provided to be bent; and
a driving element disposed on the chip on film and protruding from the chip on film to the first circuit board,
wherein an avoidance part is provided at a position corresponding to a position at which the driving element is disposed on the first circuit board.

13. The display apparatus of claim 12, wherein the avoidance part is provided as a recessed groove formed by recessing an end portion of the first circuit board.

14. The display apparatus of claim 12, wherein the avoidance part is provided as a through hole formed by penetrating the first circuit board.

15. The display apparatus of claim 12, comprising a reinforcing plate disposed at a position at which at least a portion thereof overlaps the driving element behind the chip on film and adhered to the chip on film.

16. The display apparatus of claim 12, wherein the chip on film is provided to have at least a portion adhered to the first circuit board in a state in which the driving element is accommodated in the avoidance part.

17. A display apparatus comprising:
a display panel configured to reproduce a video;
a metal plate disposed behind the display panel;
a first circuit board disposed behind the metal plate and electrically connected to the display panel;
a chip on film having one side electrically connected to the display panel, another side electrically connected to the first circuit board, and a portion provided to be bent;
a driving element disposed on the chip on film and protruding from the chip on film to the first circuit board; and
a support pad disposed between the chip on film and the first circuit board to maintain a gap between the driving element and the first circuit board.

18. The display apparatus of claim 17, wherein the support pad is provided to have a first surface adhered to at least one of the metal plate or the first circuit board.

19. The display apparatus of claim 18, wherein the support pad is provided to have a second surface adhered to the chip on film.

20. The display apparatus of claim 17, further comprising a reinforcing plate disposed at a position at which at least a portion thereof overlaps the driving element behind the chip on film and adhered to the chip on film.
